(19) United States
(12) Patent Application Publication
(10) Pub. No.: US 2025/0374574 A1
(43) Pub. Date: Dec. 4, 2025

(54) SEMICONDUCTOR DEVICE

(71) Applicant: Mitsubishi Electric Corporation, Tokyo (JP)

(72) Inventors: Tetsuya HIGASHI, Tokyo (JP); Kazuya KONISHI, Tokyo (JP)

(73) Assignee: Mitsubishi Electric Corporation, Tokyo (JP)

(21) Appl. No.: 19/183,703

(22) Filed: Apr. 18, 2025

(30) Foreign Application Priority Data
May 31, 2024 (JP) 2024-088839
Jan. 7, 2025 (JP) 2025-002111

(51) Int. Cl. H10D 12/00; H10D 64/27

(52) U.S. Cl. CPC H10D 12/481; H10D 64/513

(57) ABSTRACT

An object of the present disclosure is to provide a semiconductor device capable of achieving both improvement of trade-off of “recovery dV/dt max” and turn-on loss and reduction of a gate total load amount Qg. The semiconductor device includes: a two-part dummy active trench including an upper dummy part which is not connected to a gate electrode but is covered by an upper insulating film in an upper part and a lower electrode connected to the gate electrode and covered by a lower insulating film in a lower part inside a trench of the semiconductor substrate, wherein a film thickness of the lower insulating film in a right-left direction is larger than a film thickness of the upper insulating film in a right-left direction, and a ratio of an area of the lower insulating film to an area of the lower electrode is equal to or larger than 0.7 in a cross-sectional view.

### BACKGROUND

### Technical Field

The present disclosure relates to a semiconductor device in which power conduction is controlled by a gate signal. Description of the Background Art

Disclosed conventionally is a semiconductor device including a gate electrode formed in an upper part and a shield electrode formed in a lower part, wherein the gate electrode and the shield electrode are separated from each other via an insulating film (for example, refer to International Publication No. 2016/132552).

### SUMMARY

An emitter of a p-side semiconductor device in which a collector is connected to a high potential side (p side) and a collector of an n-side semiconductor device in which an emitter is connected to a lower potential side (n side) are connected to each other in some cases. A load is connected to a connection point between the p-side semiconductor device and the n-side semiconductor device. One free-wheeling diode is connected to each of the p-side semiconductor device and the n-side semiconductor device. The free-wheeling diode antiparallelly connected to the p-side semiconductor device is referred to as a p-side diode, and the free-wheeling diode antiparallelly connected to the n-side semiconductor device is referred to as an n-side diode.

When the p-side semiconductor device is turned on while reflux current flows in the n-side diode, recovery current flows in the n-side diode. Recovery dV/dt of the n-side diode changes in accordance with collector current of the p-side semiconductor device, for example. Specifically, recovery dV/dt of the n-side diode in turn-on loss at low current in a p-side insulated gate bipolar transistor (IGBT) is larger than recovery dV/dt at rated current of the p-side IGBT. Herein, “a low current side” indicates that the collector current of the p-side semiconductor device is small, and “a rated current side” indicates that the collector current of the p-side semiconductor device is large. When the collector current of the p-side semiconductor device small, the recovery dV/dt of the n-side diode is large. In contrast, when the collector current of the p-side semiconductor device is large, the recovery dV/dt of the n-side diode is small.

When the recovery dV/dt of the diode has current dependency in this manner, the following problem occurs. That is to say, gate resistance of the semiconductor device is set so that large recovery dV/dt has a predetermined value. For example, when the gate resistance is set so that the recovery dV/dt on the low current side is 20 kV/μs, the recovery dV/dt on the rated current side (for evaluating turn-on loss) is approximately 10 kV/μs. As a result, a switching time of the semiconductor device gets long, and the turn-on loss in a turn-on operation increases. That is to say, when the recovery dV/dt of the diode has current dependency, the turn-on loss increases.

The recovery dV/dt becomes noise. The noise gets largest (the recovery dV/dt gets largest) when the low current is switched. Herein, a maximum value of the recovery dV/dt is also referred to as “recovery dv/dt max”. When the semiconductor device is designed, “the recovery dV/dt max” needs to be equal to or smaller than a predetermined value, and the gate resistance is provided as a general method of controlling the recovery dV/dt max. However, when the gate resistance gets large, the turn-on loss is deteriorated. In this manner, there is trade-off relationship between “the recovery dV/dt max” and the turn-on loss.

The inventor of the present application found that it is effective to increase a value (Cgc/Cge) obtained by dividing gate electrode-collector electrode capacity (Cgc) of the semiconductor device by gate electrode-emitter electrode capacity (Cge) of the semiconductor device to suppress dependency of the recovery dV/dt of the free-wheeling diode on the collector current of the semiconductor device. More specifically, when the Cgc of the semiconductor device gets large, increase of the recovery dV/dt at the low current can be suppressed. When the Cge of the semiconductor device gets small, the recovery dV/dt at the large current (at the rated current) can be increased. In this manner, when the value of the Cgc/Cge gets large, the current dependency of the recovery dV/dt is improved, a switching time is reduced, and the turn-on loss can be reduced. Since increase of the recovery dV/dt at the low current can be suppressed, large gate resistance is unnecessary, and trade-off of “the recovery dV/dt max” and turn-on loss can be improved.

Since parasitic capacity cannot be adjusted in Patent Document 1, “the recovery dV/dt max” and the turn-on loss have the trade-off relationship. Accordingly, there is the problem that the turn-on loss increases as described above. Patent Document 1 does not mention reduction of a gate total load amount Qg at all.

An object of the present disclosure is to provide a semiconductor device capable of achieving both improvement of trade-off of “recovery dV/dt max” and turn-on loss and reduction of a gate total load amount Qg.

A semiconductor device according to the present disclosure includes: a semiconductor substrate; an emitter electrode formed on the semiconductor substrate; a drift layer of a first conductivity type formed in the semiconductor substrate; a base layer of a second conductivity type formed on a side of an upper surface of the semiconductor substrate; a collector electrode formed below the semiconductor substrate; and a two-part dummy active trench including an upper dummy part which is not connected to a gate electrode but is covered by an upper insulating film in an upper part and a lower electrode connected to the gate electrode and covered by a lower insulating film in a lower part inside a trench of the semiconductor substrate, wherein a film thickness of the lower insulating film in a right-left direction is larger than a film thickness of the upper insulating film in a right-left direction, and a ratio of an area of the lower insulating film to an area of the lower electrode is equal to or larger than 0.7 in a cross-sectional view.

According to the present disclosure, both improvement of trade-off of “recovery dV/dt max” and turn-on loss and reduction of a gate total load amount Qg can be achieved.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view of a semiconductor device according to an embodiment 1.

FIG. 2 is a graph illustrating a relationship between an area ratio and capacity of a lower insulating film and a lower electrode according to the embodiment 1.

FIG. 3 is a cross-sectional view of a semiconductor device according to a modification example 2 of the embodiment 1.

FIG. 4 is a cross-sectional view of a semiconductor device according to a modification example 3 of the embodiment 1.

FIG. 5 is a graph illustrating a relationship between a length from an upper end of a lower electrode to a lower end of a lower insulating film and Cge according to a modification example 3 of the embodiment 1.

FIG. 6 is a graph illustrating a relationship between the length from the upper end of the lower electrode to the lower end of the lower insulating film and Cgc/Cge according to the modification example 3 of the embodiment 1.

FIG. 7 is a cross-sectional view of a semiconductor device according to a modification example 4 of the embodiment 1.

FIG. 8 is a cross-sectional view of a semiconductor device according to a modification example 5 of the embodiment 1.

FIG. 9 is a cross-sectional view of a semiconductor device according to a modification example 6 of the embodiment 1.

FIG. 10 is a cross-sectional view of a semiconductor device according to a modification example 8 of the embodiment 1.

FIG. 11 is a cross-sectional view of a semiconductor device according to a modification example 9 of the embodiment 1.

FIG. 12 is a cross-sectional view of the semiconductor device according to the modification example 9 of the embodiment 1.

FIG. 13 is a cross-sectional view of a semiconductor device according to a modification example 10 of the embodiment 1.

FIG. 14 is a cross-sectional view of a semiconductor device according to a modification example 11 of the embodiment 1.

FIG. 15 is a cross-sectional view of a semiconductor device according to an embodiment 2.

FIG. 16 is a cross-sectional view of a semiconductor device according to a modification example 1 of the embodiment 2.

FIG. 17 is a cross-sectional view of a semiconductor device according to an embodiment 3.

FIG. 18 is a cross-sectional view of a semiconductor device according to a modification example 1 of the embodiment 3.

FIG. 19 is a cross-sectional view of a semiconductor device according to a modification example 2 of the embodiment 3.

FIG. 20 is a cross-sectional view of a semiconductor device according to a modification example 3 of the embodiment 3.

FIG. 21 is a cross-sectional view of a semiconductor device according to a modification example 4 of the embodiment 3.

FIG. 22 is a cross-sectional view of a semiconductor device according to a modification example 5 of the embodiment 3.

FIG. 23 is a cross-sectional view of a semiconductor device according to a modification example 6 of the embodiment 3.

FIG. 24 is a cross-sectional view of a semiconductor device according to a modification example 7 of the embodiment 3.

FIG. 25 is a cross-sectional view of a semiconductor device according to a modification example 8 of the embodiment 3.

FIG. 26 is a cross-sectional view of a semiconductor device according to a modification example 9 of the embodiment 3.

FIG. 27 is a cross-sectional view of a semiconductor device according to a modification example 10 of the embodiment 3.

FIG. 28 is a cross-sectional view of a semiconductor device according to a modification example 11 of the embodiment 3.

FIG. 29 is a cross-sectional view of a semiconductor device according to an embodiment 4.

FIG. 30 is a cross-sectional view of a semiconductor device according to a modification example 1 of the embodiment 4.

FIG. 31 is a cross-sectional view of a semiconductor device according to another example of the modification example 1 of the embodiment 4.

FIG. 32 is a plan view of a contact lifting part of a semiconductor device according to an embodiment 5.

FIG. 33 is a cross-sectional view along an A-A line in FIG. 32.

FIG. 34 is a cross-sectional view along an A-A line in FIG. 32.

### DESCRIPTION OF THE PREFERRED EMBODIMENTS

A semiconductor device according to an embodiment is described hereinafter with reference to the diagrams. The same signs are assigned to the same or corresponding constituent elements, and a repetitive description is omitted in some cases. In the description hereinafter, n and p indicate a conductivity type of a semiconductor, and a first conductivity type is an n type and a second conductivity type is a p type in the present disclosure. These conductivity types may be reversed.

### Embodiment 1

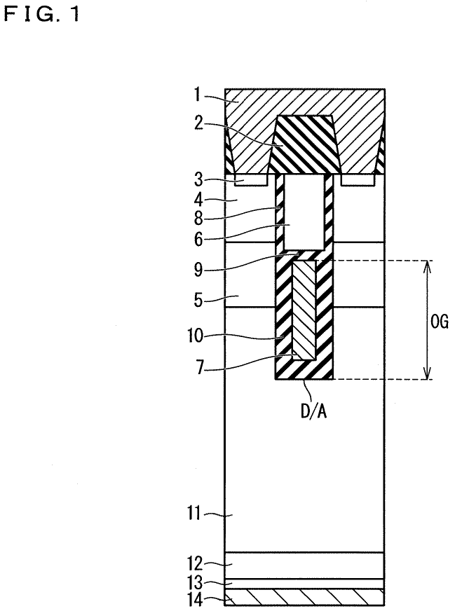

FIG. 1 is a cross-sectional view of a semiconductor device according to an embodiment 1. The semiconductor device illustrated in FIG. 1 constitutes an insulated gate bipolar transistor (IGBT).

As illustrated in FIG. 1, a two-part dummy active trench D/A is provided to a semiconductor substrate. The two-part dummy active trench D/A includes an upper dummy part 6 which is not connected to a gate electrode (not shown) in an upper part and a lower electrode 7 connected to the gate electrode in a lower part inside the trench of the semiconductor substrate. The upper dummy part 6 is covered by an upper insulating film 8, and the lower electrode 7 is covered by a lower insulating film 10. The two-part dummy active trench D/A includes a boundary insulating film 9 between the upper dummy part 6 and the lower electrode 7, and the upper dummy part 6 and the lower electrode 7 are electrically separated from each other via the boundary insulating film 9. The boundary insulating film 9 faces a drift layer 11. “The trench” indicates a hole provided to the semiconductor substrate or a structure formed in the hole.

In FIG. 1, the semiconductor substrate ranges from a contact layer 3 to a collector layer 13. In FIG. 1, an upper end of a paper sheet of the contact layer 3 is referred to as a first main surface of the semiconductor substrate, and a lower end of a paper sheet of the collector layer 13 is referred to as a second main surface of the semiconductor substrate. The first main surface of the semiconductor substrate is a main surface of the semiconductor device on a front surface side, and the second main surface of the semiconductor substrate is a main surface of the semiconductor device on a back surface side. The first main surface and the second main surface face each other. The semiconductor device includes the n-type drift layer 11 between the first main surface and the second main surface.

An n-type carrier accumulation layer 5 having a higher n-type impurity concentration than the drift layer 11 is provided to the drift layer 11 on a side of the first main surface. The carrier accumulation layer 5 is provided between a base layer 4 and the drift layer 11. The carrier accumulation layer 5 and the drift layer 11 may be collectively referred to as a drift layer. The semiconductor device may have a configuration that the drift layer 11 is provided also to a region of the carrier accumulation layer 5 illustrated in FIG. 1 without providing the carrier accumulation layer 5.

The p-type base layer 4 is provided to the carrier accumulation layer 5 on the side of the first main surface. The base layer 4 has contact with the upper insulating film 8 of the two-part dummy active trench D/A.

The p-type contact layer 3 is provided to the base layer 4 on the side of the first main surface. The contact layer 3 is a region having a high p-type impurity concentration than the base layer 4, and each of the contact layer 3 and the base layer 4 may be individually referred when they need to be distinguished from each other. The contact layer 3 and the base layer 4 may also be collectedly referred to as the p-type base layer.

An interlayer insulating film 2 is provided on the upper dummy part 6 of the two-part dummy active trench D/A. An emitter electrode 1 is provided on a region where the interlayer insulating film 2 is not provided in the first main surface of the semiconductor device and on the interlayer insulating film 2. It is also applicable in FIG. 1 that the interlayer insulating film 2 is not provided but the emitter electrode 1 is directly provided on the upper dummy part 6. As illustrated in FIG. 1, when the interlayer insulating film 2 is provided on the upper dummy part 6, it is sufficient that the emitter electrode 1 and the upper dummy part 6 are electrically connected to each other in the other cross section.

An n-type buffer layer 12 having a higher n-type impurity concentration than the drift layer 11 is provided to the drift layer 11 on a side of the second main surface. The buffer layer 12 is provided to suppress punch-through of a depletion layer extending from the base layer 4 to the side of the second main surface when the semiconductor device is in an off state. The semiconductor device may have a configuration that the drift layer 11 is provided also to the buffer layer 12 illustrated in FIG. 1 without providing the buffer layer 12. The buffer layer 12 and the drift layer 11 may be collectively referred to as the drift layer.

The p-type collector layer 13 is provided to the buffer layer 12 on the side of the second main surface. That is to say, the collector layer 13 is provided between the drift layer 11 and the second main surface.

A collector electrode 14 is provided to the collector layer 13 on the side of the second main surface. The collector electrode 14 is provided below the semiconductor substrate. The collector electrode 14 has ohmic-contact with the collector layer 13, and is electrically connected thereto.

A film thickness of the lower insulating film 10 in a right-left direction is larger than that of the upper insulating film 8 in a right-left direction in the two-part dummy active trench D/A. In a cross-sectional view, a ratio of an area of the lower insulating film 10 to an area of the lower electrode 7 is equal to or larger than 0.7. Herein, the right-left direction is a direction perpendicular to a depth direction of the two-part dummy active trench D/A (a width direction of the two-part dummy active trench D/A).

A film thickness of the lower insulating film 10 in an up-down direction is preferably larger than that of the upper insulating film 8 in a right-left direction in the two-part dummy active trench D/A, and Qg can be effectively reduced. Furthermore, the film thickness of the lower insulating film 10 in the up-down direction may be larger than that of the lower insulating film 10 in the right-left direction.

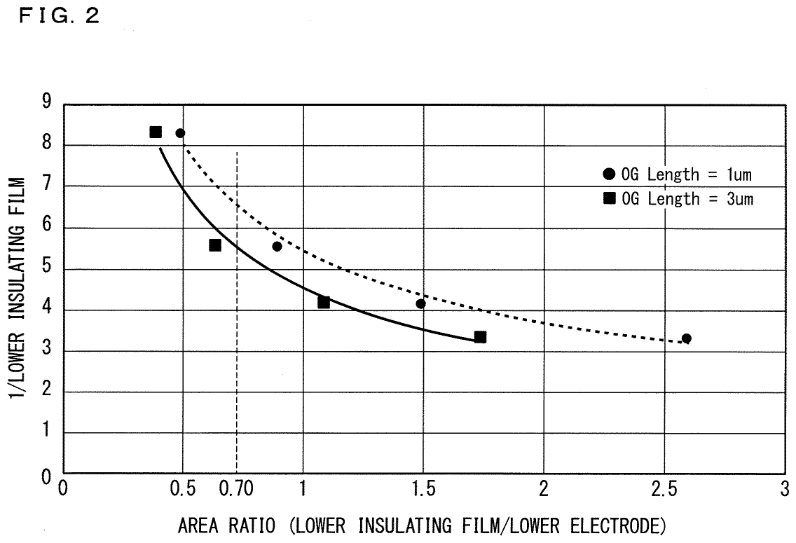

FIG. 2 is a graph illustrating a relationship between an area ratio and capacity of the lower insulating film 10 and the lower electrode 7. In FIG. 2, a vertical axis indicates an inverse number (capacity) of the lower insulating film 10. A lateral axis indicates an area ratio of the lower insulating film 10 and the lower electrode 7. “0G” indicates a length from an upper end (an end portion on a side of the first main surface) of the lower electrode 7 and the lower insulating film 10 to a lower end of the lower insulating film 10 (an end portion on the side of the second main surface)

FIG. 2 shows that as the area of the lower insulating film 10 gets larger with respect to the area of the lower electrode 7 (as the film thickness of the lower insulating film 10 gets larger), the capacity decreases. That is to say, the capacity can be adjusted by changing the film thickness of the lower insulating film 10. Particularly, when the area ratio of the lower insulating film 10 to the lower electrode 7 is equal to or larger than 0.7, the capacity further gets smaller.

According to the embodiment 1, the two-part dummy active trench D/A includes the upper dummy part 6 and the lower electrode 7. Accordingly, when a value of the Cgc/Cge gets large, current dependency of recovery dV/dt is improved, a switching time is reduced, and turn-on loss can be reduced. Since increase of the recovery dV/dt at low current can be suppressed, large gate resistance is unnecessary, and trade-off of “the recovery dV/dt max” and turn-on loss can be improved. When the ratio of the area of the lower insulating film 10 to the area of the lower electrode 7 is equal to or larger than 0.7 in a cross-sectional view, a gate total load amount Qg can be effectively reduced.

### Modification Example 1

In FIG. 1, the area of the lower electrode 7 may be smaller than the area of the upper dummy part 6. According to such a configuration, the Cgc gets smaller, but the gate total load amount Qg can be reduced compared with the configuration in the embodiment 1.

### Modification Example 2

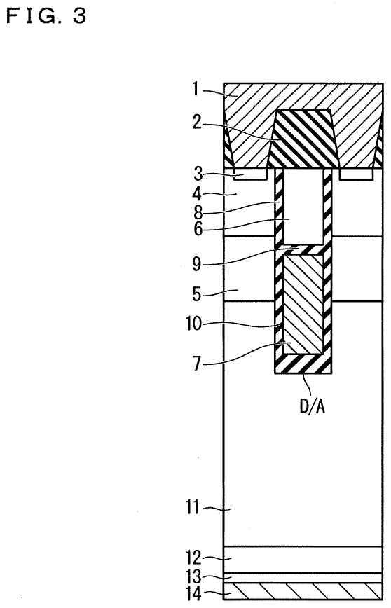

FIG. 3 is a cross-sectional view of a semiconductor device according to a modification example 2 of the embodiment 1.

As illustrated in FIG. 3, in the semiconductor device according to the modification example 2, the area of the lower electrode 7 is larger than that of the upper dummy part 6 in a cross-sectional view. According to such a configuration, the Cgc gets large, and “the recovery dV/dt max” can be reduced compared with the configuration according to the embodiment 1.

### Modification Example 3

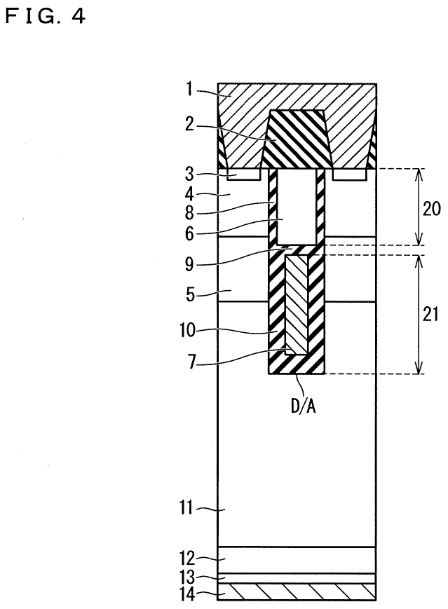

FIG. 4 is a cross-sectional view of a semiconductor device according to a modification example 3 of the embodiment 1.

As illustrated in FIG. 4, in the semiconductor device according to the modification example 3, a length 21 of the lower electrode 7 in the up-down direction is larger than a length 20 of the upper dummy part 6 in the up-down direction. Herein, the up-down direction is a depth direction of the two-part dummy active trench D/A.

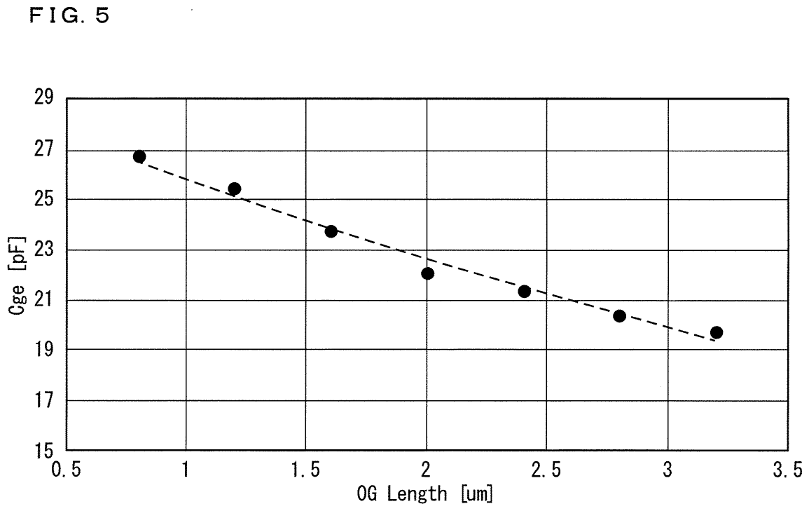

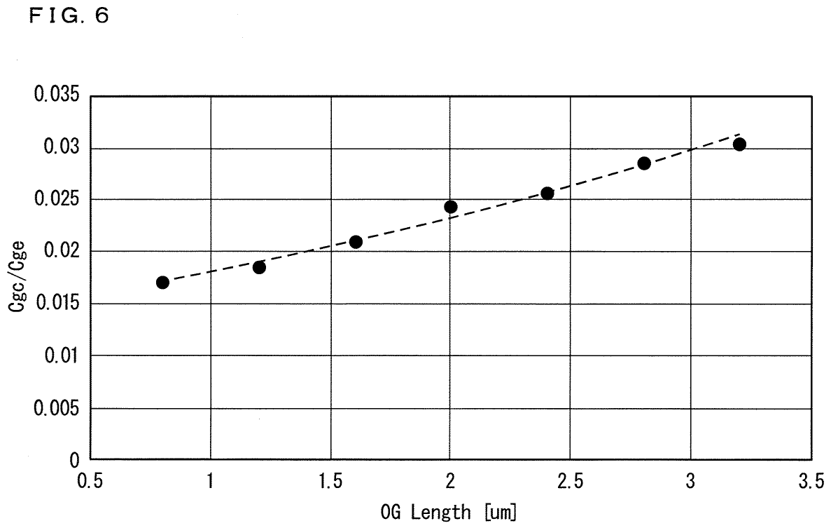

FIG. 5 is a graph illustrating a relationship between a length (length of 0G) from the upper end of the lower electrode to the lower end of the lower insulating film and Cge. FIG. 6 is a graph illustrating a relationship between the length from the upper end of the lower electrode to the lower end of the lower insulating film and Cgc/Cge. As illustrated in FIGS. 5 and 6, when the length of 0G gets large, the Cge gets small, and the Cgc/Cge gets large. When the length of 0G gets large, the Cgc gets large.

According to such a configuration, the Cgc gets large, and “the recovery dV/dt max” can be reduced compared with the configuration according to the embodiment 1.

### Modification Example 4

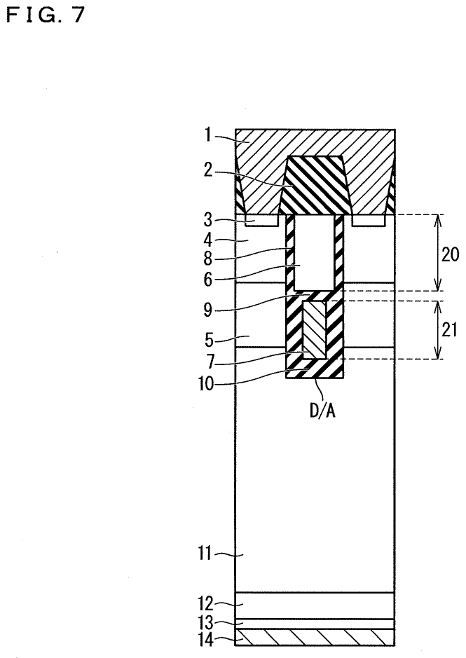

FIG. 7 is a cross-sectional view of a semiconductor device according to a modification example 4 of the embodiment 1.

As illustrated in FIG. 7, in the semiconductor device according to the modification example 4, the length 21 of the lower electrode 7 in the up-down direction is smaller than the length 20 of the upper dummy part 6 in the up-down direction. According to such a configuration, the Cgc gets smaller, but the gate total load amount Qg can be reduced compared with the configuration in the embodiment 1.

### Modification Example 5

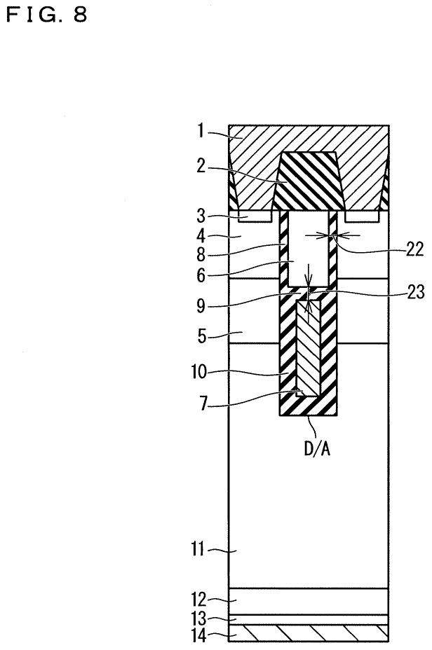

FIG. 8 is a cross-sectional view of a semiconductor device according to a modification example 5 of the embodiment 1.

As illustrated in FIG. 8, in the semiconductor device according to the modification example 5, a film thickness 23 of the boundary insulating film 9 in the up-down direction is smaller than a film thickness 22 of the upper insulating film 8 in the right-left direction.

According to such a configuration, insulation properties gets high between the upper dummy part 6 and the lower electrode 7; thus, such a configuration contributes to improvement of reliability of the semiconductor device.

### Modification Example 6

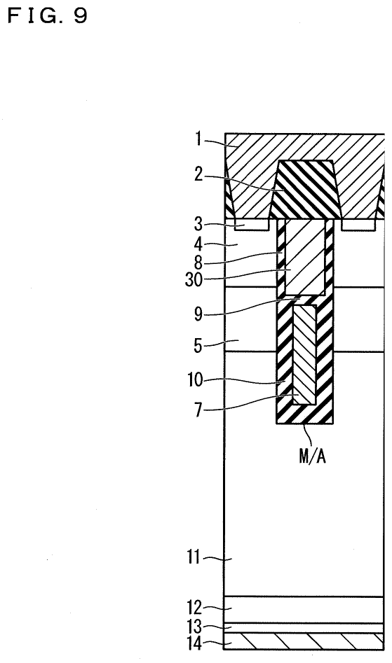

FIG. 9 is a cross-sectional view of a semiconductor device according to a modification example 6 of the embodiment 1. In the semiconductor device according to the modification example 6, the upper dummy part is metal 30.

The metal 30 may be the same material as the emitter electrode 1, for example. In this case, the metal 30 is provided as a part of the emitter electrode 1. As illustrated in FIG. 9, a trench including the metal 30 as the upper dummy part and the lower electrode 7 is referred to as a two-part metal active trench M/A.

Since the upper dummy part is the metal 30, drawability of a hole can be improved. Accordingly, a reverse bias safe operation area (RBSOA) can be improved.

### Modification Example 7

In FIG. 1, the upper dummy part 6 may have higher specific resistance than the lower electrode 7. Alternatively, the upper dummy part 6 may have lower specific resistance than the lower electrode 7.

### Modification Example 8

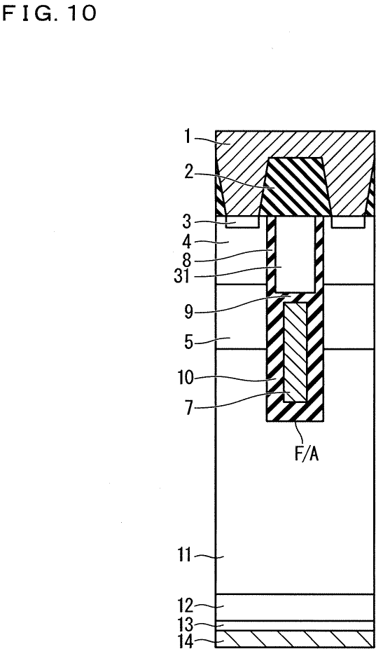

FIG. 10 is a cross-sectional view of a semiconductor device according to a modification example 8 of the embodiment 1. In the semiconductor device according to the modification example 8, an upper dummy part 31 is floating potential. As illustrated in FIG. 10, a trench including the upper dummy part 31 as the floating potential and the lower electrode 7 is referred to as a two-part floating active trench F/A.

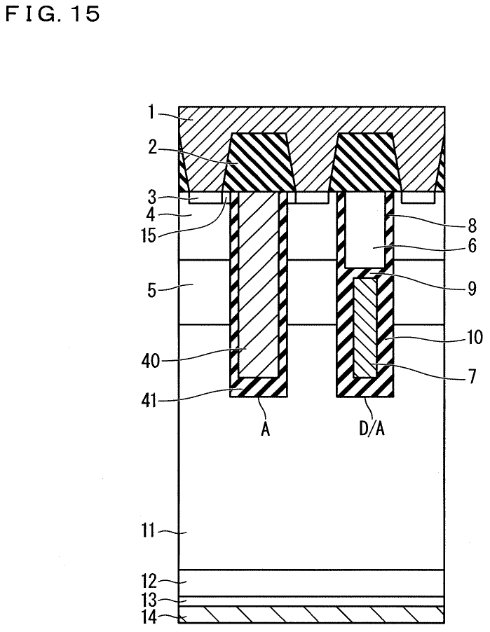

When the upper dummy part 31 as the floating potential is provided, the Cge occurring between an active trench A (refer to FIG. 15) and the upper dummy part 31 of the two-part dummy active trench D/A can be reduced. Accordingly, the value of the Cgc/Cge can be further increased.

### Modification Example 9

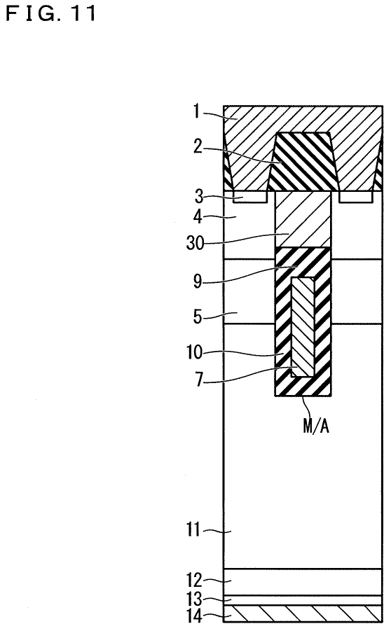

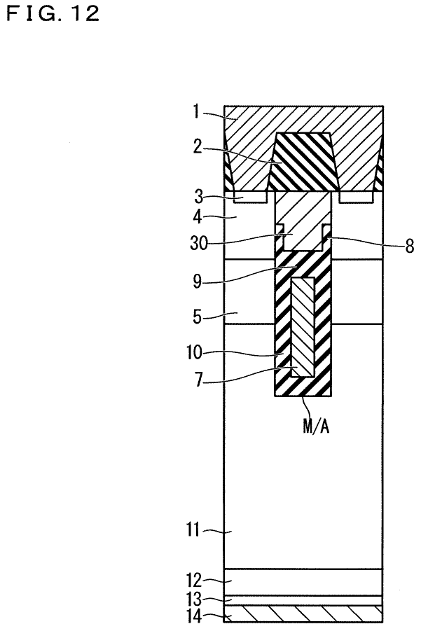

FIGS. 11 and 12 are cross-sectional views of a semiconductor device according to a modification example 9 of the embodiment 1. As illustrated in FIGS. 11 and 12, in the semiconductor device according to the modification example 9, the metal 30 as the upper dummy part has partially contact with the base layer 4. As illustrated in FIG. 12, the upper insulating film 8 may have a concave shape in a cross-sectional view.

In the semiconductor device, a hole passes through the collector layer 13, the drift layer 11, the carrier accumulation layer 5, the base layer 4, and the contact layer 3 from the second main surface, and is discharged from the first main surface. When the metal 30 is provided as illustrated in FIGS. 11 and 12, the hole is discharged via the metal 30 having low electrical resistance. Thus, drawability of the hole can be improved.

When the upper insulating film 8 has the concave shape as illustrated in FIG. 12, the metal 30 can be prevented from having contact with the carrier accumulation layer 5.

Accordingly, the metal 30 can be provided in a deep position; thus, the area of the lower electrode 7 can be reduced to increase an effect of reducing the gate total load amount Qg.

### Modification Example 10

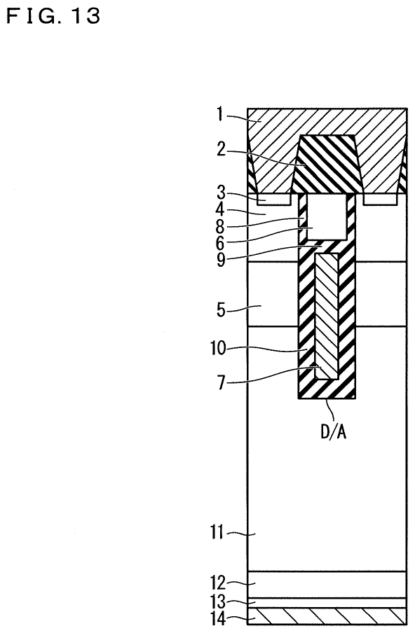

FIG. 13 is a cross-sectional view of a semiconductor device according to a modification example 10 of the embodiment 1. As illustrated in FIG. 13, in the semiconductor device according to the modification example 10, the boundary insulating film 9 faces the base layer 4. A position of the upper end of the lower electrode 7 is located higher than a position of the lower end of the base layer 4.

As illustrated in FIG. 1, when the position of the upper end of the lower electrode 7 is located lower than the position of the lower end of the base layer 4, there is a region in which the lower electrode 7 and the drift layer 11 or the carrier accumulation layer 5 do not face each other in the right-left direction above the lower electrode 7, and the Cgc does not occur in the region. In the meanwhile, as illustrated in FIG. 13, the Cgc can be increased by preventing formation of the region in which the lower electrode 7 and the drift layer 11 or the carrier accumulation layer 5 do not face each other in the right-left direction above the lower electrode 7.

### Modification Example 11

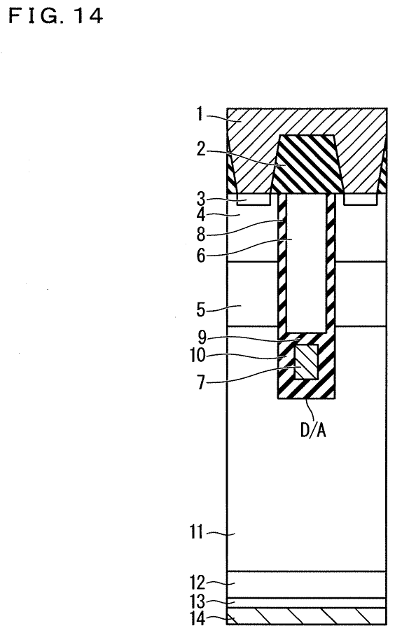

FIG. 14 is a cross-sectional view of a semiconductor device according to a modification example 11 of the embodiment 1. As illustrated in FIG. 14, the lower electrode 7 faces only the drift layer 11 in the right-left direction via the lower insulating film 10. The position of the upper end of the lower electrode 7 is located lower than the position of the lower end of the carrier accumulation layer 5.

When the hole implanted from the second main surface in a turn-on operation changes the potential of the base layer 4, oscillation of the gate potential occurs by displacement current flowing from the base layer 4 to the lower electrode 7, and controllability of dV/dt worsens. This phenomenon is particularly significant in a case where the base layer 4 is floating and a case where a distance from the lower electrode 7 to the base layer 4 is small. As illustrated in FIG. 14, when the lower electrode 7 is located away from the base layer 4, a negative effect such as oscillation of the gate can be suppressed.

The length of the lower electrode 7 in the up-down direction may be smaller than that of the lower electrode 7 in the right-left direction.

### Embodiment 2

Described in an embodiment 2 is a semiconductor device in which the two-part dummy active trench D/A and the active trench A are provided adjacent to each other.

FIG. 15 is a cross-sectional view of the semiconductor device according to the embodiment 2. As illustrated in FIG. 15, the semiconductor device according to the embodiment 2 includes the two-part dummy active trench D/A and the active trench A. The two-part dummy active trench D/A corresponds to the two-part dummy active trench D/A illustrated in FIG. 1.

The active trench A includes a gate insulating film 41 provided along the trench of the semiconductor substrate and an active part 40 provided to have contact with the gate insulating film 41 and connected to the gate electrode.

An n-type source layer 15 is provided to have contact with the gate insulating film 41 on both sides of the active trench A in the right-left direction. The carrier accumulation layer 5 has a lower n-type impurity concentration than the source layer 15, and has a higher n-type impurity concentration than the drift layer 11. The carrier accumulation layer 5 is provided; thus, power conduction loss at a time of flowing current can be reduced.

### Modification Example 1

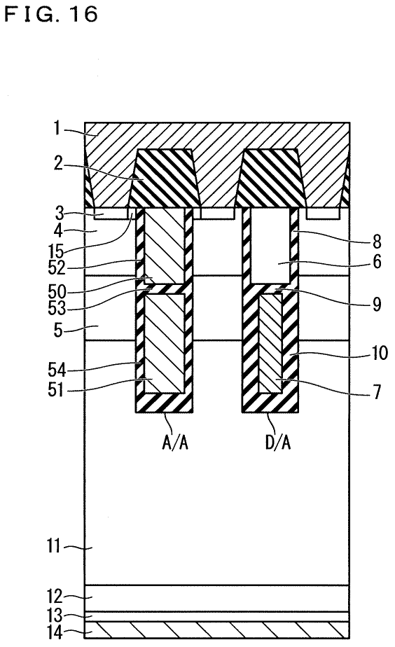

FIG. 16 is a cross-sectional view of a semiconductor device according to a modification example 1 of an embodiment 2. As illustrated in FIG. 16, the semiconductor device according to the modification example 1 includes the two-part dummy active trench D/A and a two-part active trench A/A.

The two-part active trench A/A includes an upper active part 50 connected to the gate electrode in an upper part and a lower active part 51 connected to the gate electrode in a lower part inside the trench of the semiconductor substrate. The upper active part 50 is covered by an upper insulating film 52, and the lower active part 51 is covered by a lower insulating film 54. A boundary insulating film 53 is provided between the upper active part 50 and the lower active part 51, and the upper active part 50 and the lower active part 51 are electrically separated from each other via the boundary insulating film 53.

### Embodiment 3

In a case of a trench arrangement in which the active trench A and the upper dummy part 6 of the two-part dummy active trench D/A are located adjacent to each other as illustrated in FIG. 15, since the upper dummy part 6 as emitter potential (not gate potential) is disposed adjacent to the active trench A as gate potential, for example, the Cge occurs as coupling capacity between the active trench A and the upper dummy part 6. Reduction of the coupling capacity Cge is described in an embodiment 3.

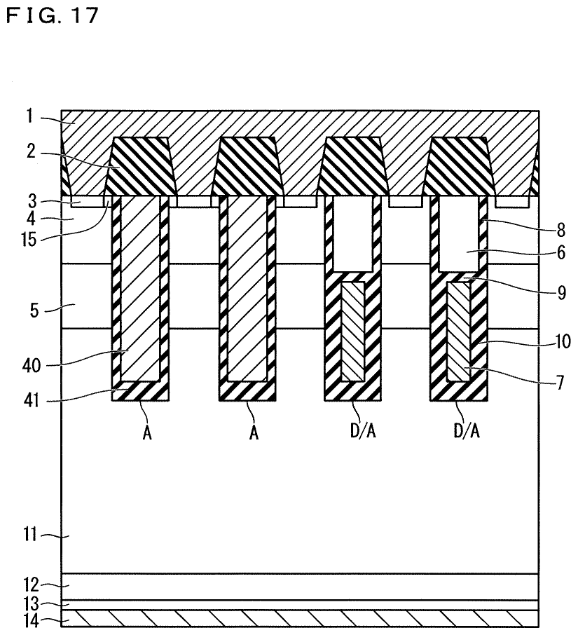

FIG. 17 is a cross-sectional view of a semiconductor device according to the embodiment 3. As illustrated in FIG. 17, in the semiconductor device according to the embodiment 3, two active trenches A are provided side by side, and two two-part dummy active trenches D/A are provided side by side. A set of the two active trenches A and a set of the two two-part dummy active trenches D/A are alternately provided. When the active trenches A are disposed in a bundle and the two-part dummy active trenches D/A are disposed in a bundle, a density of adjacency between the active trench A and the two-part dummy active trench D/A is smaller than a case where one active trench A and one two-part dummy active trench D/A are alternately provided. Accordingly, the coupling capacity Cge between the active trench A and the two-part dummy active trench D/A can be reduced while the Cgc is maintained.

Although FIG. 17 illustrates an example of a case where two active trenches A and two two-part dummy active trenches D/A are provided, it is sufficient that two or more active trenches A or two or more two-part dummy active trenches D/A are provided side by side or both the two or more active trenches A and the two or more two-part dummy active trenches D/A are provided side by side.

### Modification Example 1

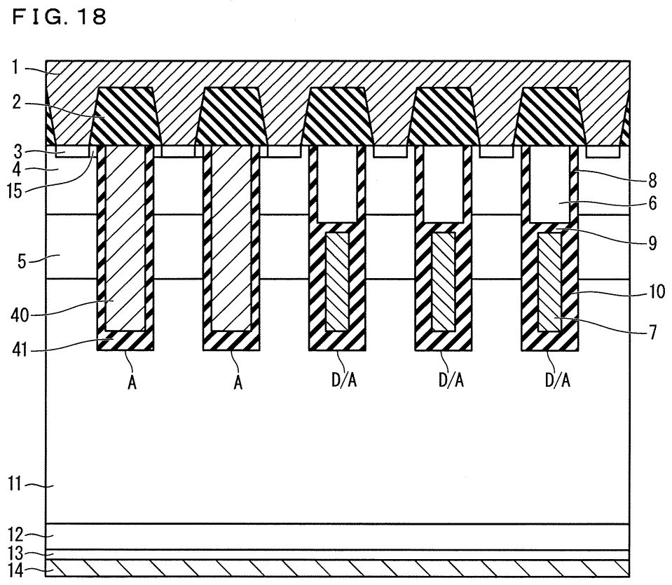

FIG. 18 is a cross-sectional view of a semiconductor device according to a modification example 1 of the embodiment 3. As illustrated in FIG. 18, the number of two-part dummy active trenches D/A is larger than that of active trenches A. As the number of two-part dummy active trenches D/A gets larger, the effect of reducing the coupling capacity Cge increases.

### Modification Example 2

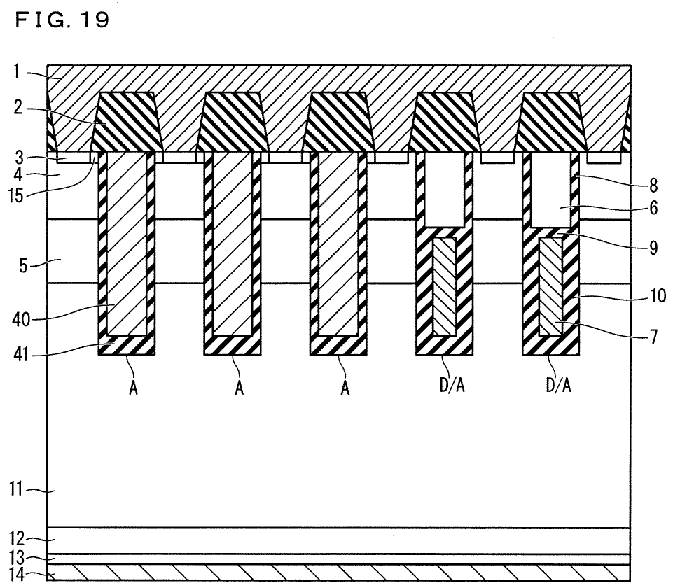

FIG. 19 is a cross-sectional view of a semiconductor device according to a modification example 2 of the embodiment 3. As illustrated in FIG. 19, the number of two-part dummy active trenches D/A may be smaller than that of active trenches A.

### Modification Example 3

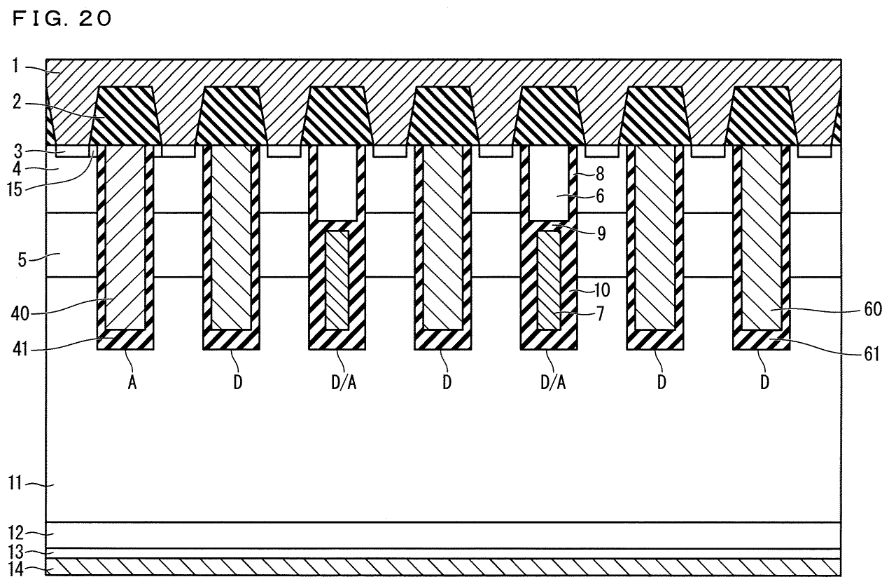

FIG. 20 is a cross-sectional view of a semiconductor device according to a modification example 3 of the embodiment 3. The semiconductor device according to the modification example 3 includes the two-part dummy active trench D/A, the active trench A, and a dummy trench D.

The dummy trench D includes an insulating film 61 provided along the trench of the semiconductor substrate and a dummy part 60 which is provided to have contact with the insulating film 61 but is not connected to the gate electrode. The dummy part 60 is electrically connected to the emitter electrode 1, for example.

The gate capacity can be adjusted by changing a proportion of the dummy trench D in the whole trenches in the semiconductor device.

### Modification Example 4

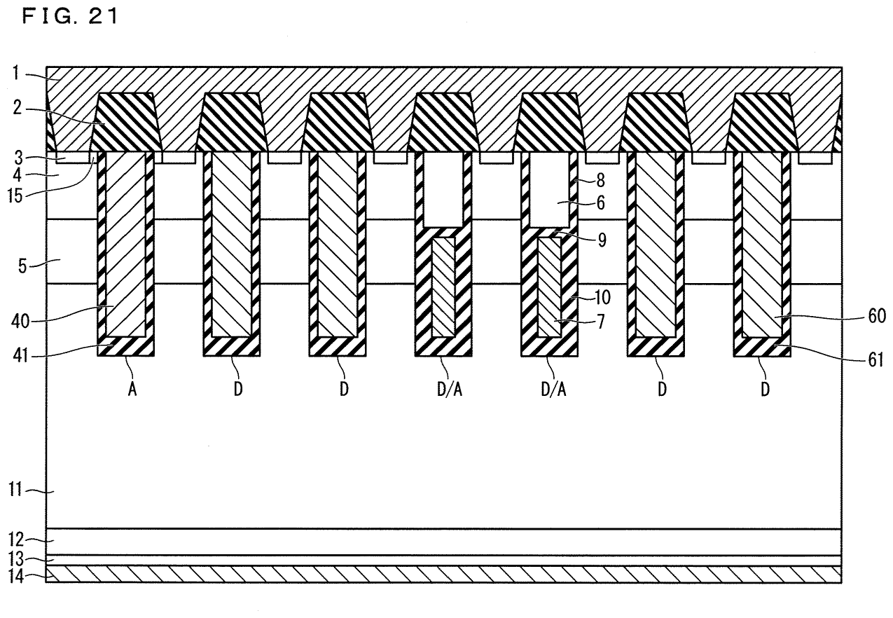

FIG. 21 is a cross-sectional view of a semiconductor device according to a modification example 4 of the embodiment 3. In the semiconductor device according to the modification example 4, two two-part dummy active trenches D/A are provided side by side. Two or more two-part dummy active trenches D/A may be provided side by side.

Since two or more two-part dummy active trenches D/A are provided side by side, the Cge occurring between the lower electrode 7 and the dummy trench D can be reduced. Accordingly, the value of the Cgc/Cge can be increased.

### Modification Example 5

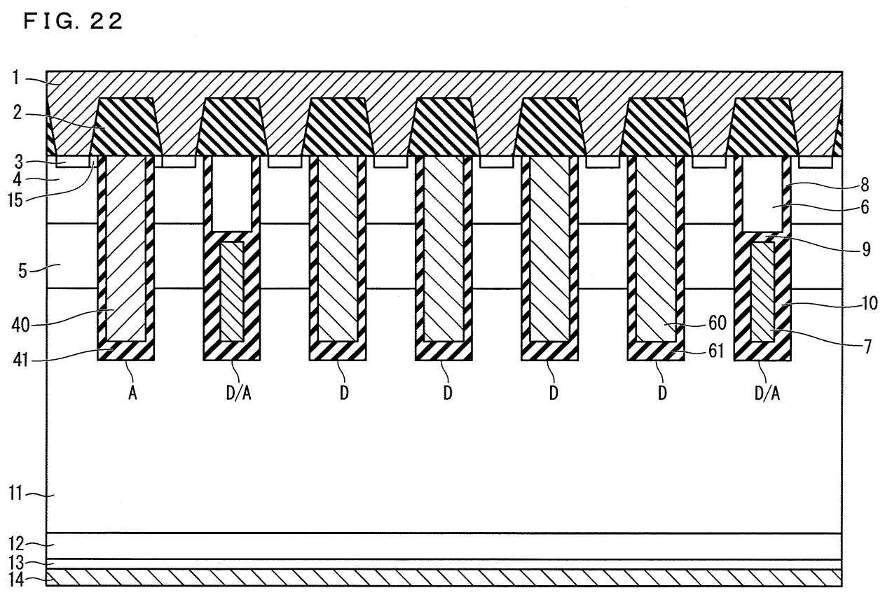

FIG. 22 is a cross-sectional view of a semiconductor device according to a modification example 5 of the embodiment 3. In the semiconductor device according to the modification example 5, two or more dummy trenches D are provided side by side. The two-part dummy active trench D/A and the active trench A are provided side by side.

When the two-part dummy active trench D/A and the active trench A are provided side by side and the dummy trenches D are provided side by side, the Cge occurring between the lower electrode 7 and the dummy trench D and the Cge occurring between the active trench A and the dummy trench D can be reduced. Accordingly, the value of the Cgc/Cge can be increased.

### Modification Example 6

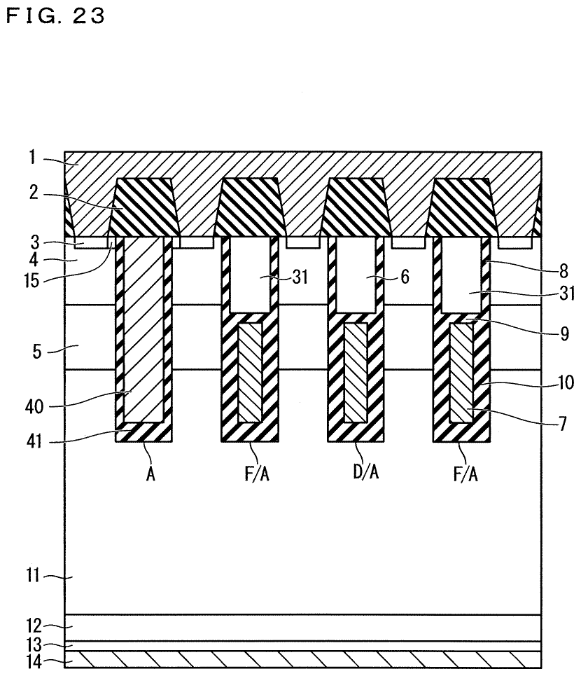

FIG. 23 is a cross-sectional view of a semiconductor device according to a modification example 6 of the embodiment 3. The semiconductor device according to the modification example 6 includes the two-part dummy active trench D/A, the active trench A, and the two-part floating active trench F/A.

The two-part floating active trench F/A includes the upper dummy part 31 as the floating potential covered by the upper insulating film 8 in an upper part and the lower electrode 7 connected to the gate electrode and covered by the lower insulating film 10 in a lower part inside the trench of the semiconductor substrate.

According to such a configuration, the coupling capacity Cge occurring between the active trench A and the upper dummy part 6 of the two-part dummy active trench D/A can be reduced. Accordingly, the value of the Cgc/Cge can be increased.

### Modification Example 7

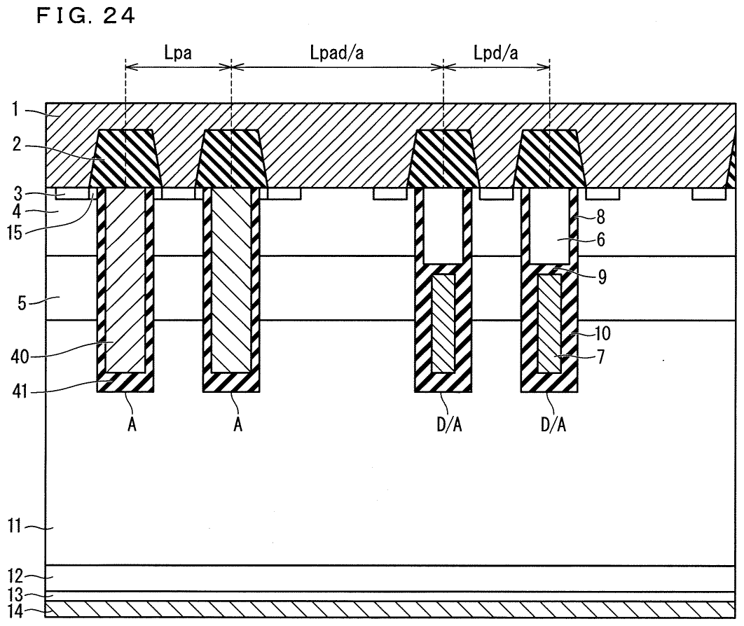

FIG. 24 is a cross-sectional view of a semiconductor device according to a modification example 7 of the embodiment 3. In the semiconductor device according to the modification example 7, an interval (Lpad/a) between two or more two-part dummy active trenches D/A provided side by side and two or more active trenches A provided side by side is larger than an interval (Lpd/a) between two two-part dummy active trenches D/A adjacent to each other, and is larger than an interval (Lpa) between two active trenches A adjacent to each other.

Since the interval (Lpad/a) between two or more two-part dummy active trenches D/A provided side by side and two or more active trenches A provided side by side is large, the coupling capacity Cge occurring between the active trench A and the upper dummy part 6 of the two-part dummy active trench D/A can be reduced. Accordingly, the value of the Cgc/Cge can be increased.

### Modification Example 8

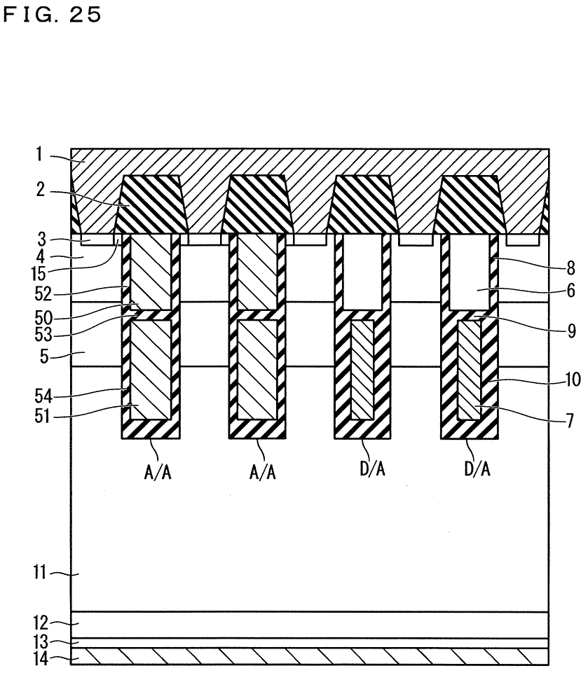

FIG. 25 is a cross-sectional view of a semiconductor device according to a modification example 8 of the embodiment 3. As illustrated in FIG. 25, in the semiconductor device according to the modification example 8, two two-part active trenches A/A are provided side by side, and two two-part dummy active trenches D/A are provided side by side. A set of the two two-part active trenches A/A and a set of the two two-part dummy active trenches D/A are alternately provided. When the two-part active trenches A/A are disposed in a bundle and the two-part dummy active trenches D/A are disposed in a bundle, a density of adjacency between the two-part active trench A/A and the two-part dummy active trench D/A is smaller than the case where one two-part active trench A/A and one two-part dummy active trench D/A are alternately provided. Accordingly, the coupling capacity Cge between the two-part active trench A/A and the two-part dummy active trench D/A can be reduced while the Cgc is maintained.

Although FIG. 25 illustrates an example of a case where two two-part active trenches A/A and two two-part dummy active trenches D/A are provided, it is sufficient that two or more two-part active trenches A/A or two or more two-part dummy active trenches D/A are provided side by side or both the two or more two-part active trenches A/A and the two or more two-part dummy active trenches D/A are provided side by side.

### Modification Example 9

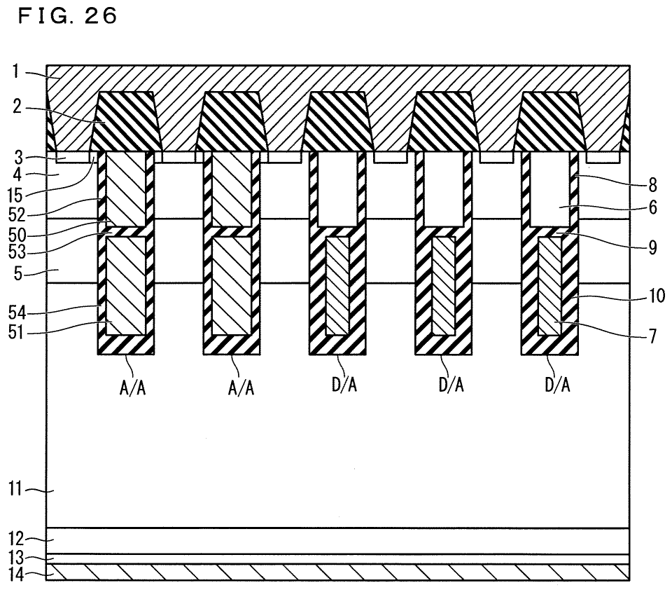

FIG. 26 is a cross-sectional view of a semiconductor device according to a modification example 9 of the embodiment 3. As illustrated in FIG. 26, the number of two-part dummy active trenches D/A is larger than that of two-part active trenches A/A. As the number of two-part dummy active trenches D/A gets larger, the effect of reducing the coupling capacity Cge increases.

### Modification Example 10

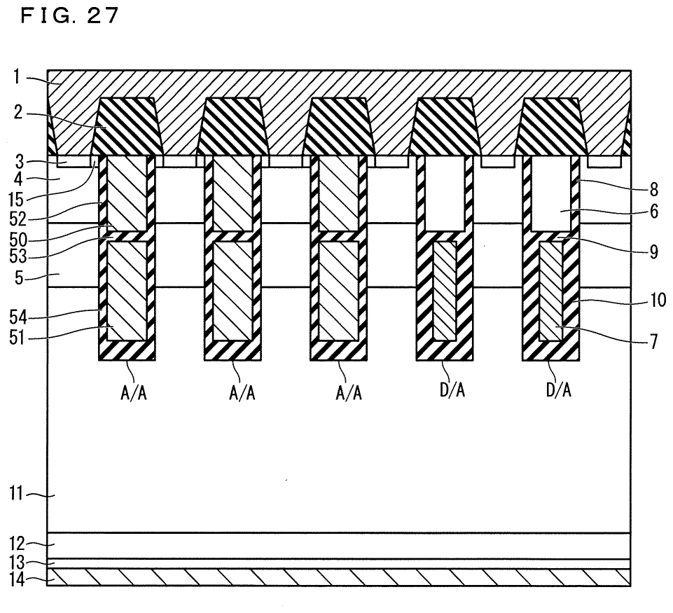

FIG. 27 is a cross-sectional view of a semiconductor device according to a modification example 10 of the embodiment 3. As illustrated in FIG. 27, the number of two-part dummy active trenches D/A may be smaller than that of two-part active trenches A/A.

### Modification Example 11

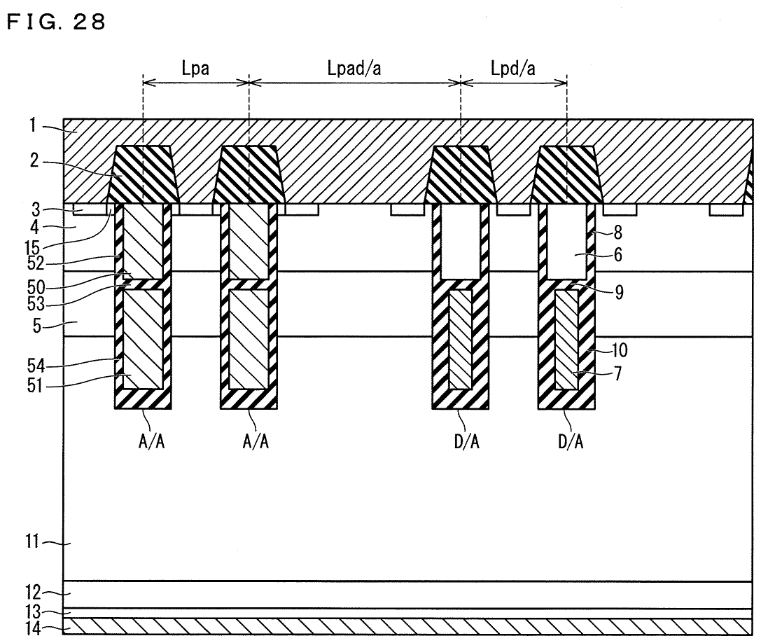

FIG. 28 is a cross-sectional view of a semiconductor device according to a modification example 11 of the embodiment 3. In the semiconductor device according to the modification example 11, an interval (Lpad/a) between two or more two-part dummy active trenches D/A provided side by side and two or more two-part active trenches A/A provided side by side is larger than an interval (Lpd/a) between two two-part dummy active trenches D/A adjacent to each other, and is larger than an interval (Lpa) between two two-part active trenches A/A adjacent to each other.

Since the interval (Lpad/a) between two or more two-part dummy active trenches D/A provided side by side and two or more two-part active trenches A/A provided side by side is large, the coupling capacity Cge occurring between the two-part active trench A/A and the upper dummy part 6 of the two-part dummy active trench D/A can be reduced. Accordingly, the value of the Cgc/Cge can be increased.

### Embodiment 4

Double gate driving is proposed as a method of achieving both reduction of on resistance and reduction of switching loss. The double gate driving is a technique of setting two gate drive systems and changing a driving timing of two gates, thereby reducing a switching timing of the IGBT and reducing switching loss. Specifically, a gate of I system is turned off before a turn-off operation and a channel is closed to reduce carriers in the drift layer before shut-off. Accordingly, both reduction of on resistance and reduction of switching loss can be achieved.

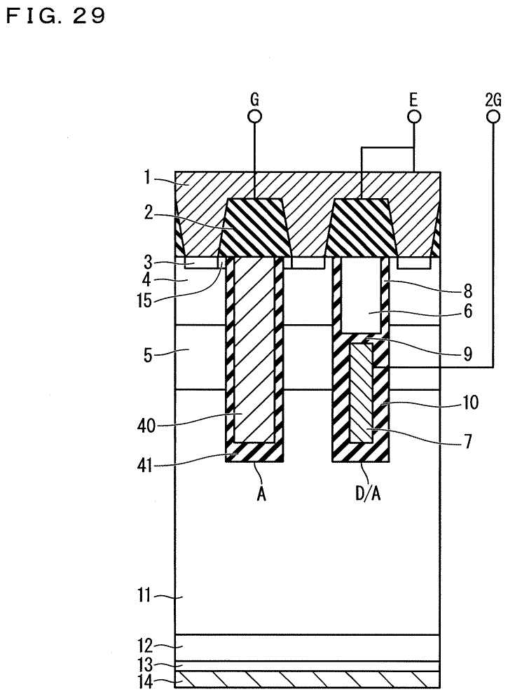

FIG. 29 is a cross-sectional view of a semiconductor device according to an embodiment 4. The gate electrode includes a first gate electrode G and a second gate electrode 2G of a system different from the first gate electrode G. The active part 40 of the active trench A is connected to the first gate electrode G, and the lower electrode 7 of the two-part dummy active trench D/A is connected to the second gate electrode 2G.

### Modification Example 1

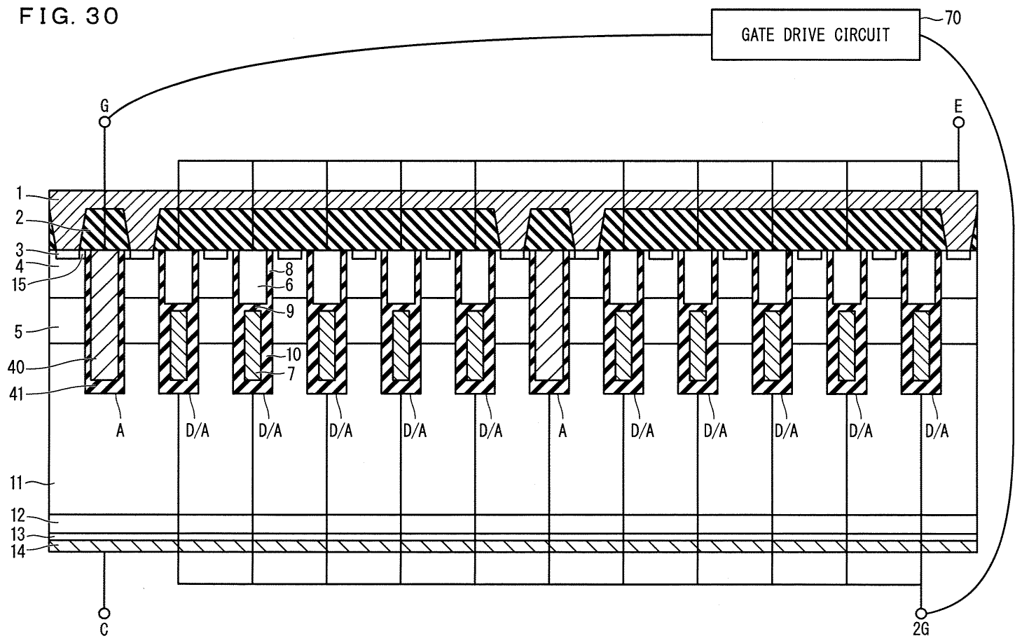

FIG. 30 is a cross-sectional view of a semiconductor device according to a modification example 1 of the embodiment 4. The gate electrode includes the first gate electrode G and the second gate electrode 2G of the system different from the first gate electrode G. The first gate electrode G and the second gate electrode 2G are connected to a gate drive circuit 70. The active trench A includes a first active trench A1 and a second active trench A2. The active part 40 of the first active trench A1 is connected to the first gate electrode G. The active part 40 of the second active trench A2 and the lower electrode 7 of the two-part dummy active trench D/A are connected to the second gate electrode 2G.

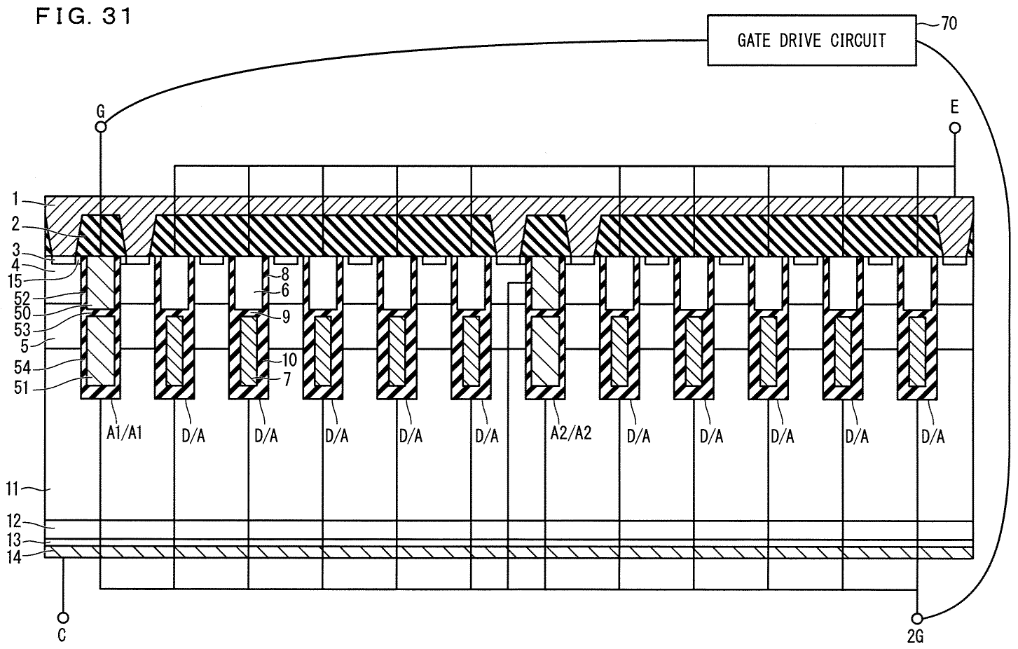

FIG. 31 is a cross-sectional view of a semiconductor device according to another example of the modification example 1 of the embodiment 4. The two-part active trench A/A includes a two-part active trench A1/A1 and a two-part active trench A2/A2. The upper active part 50 of the two-part active trench A1/A1 is connected to the first gate electrode G. A lower active part 51 of the two-part active trench A1/A2, the upper active part 50 of the two-part active trench A2/A2, the lower active part 51 of the two-part active trench A2/A2, and the lower electrode 7 of the two-part dummy active trench D/A are connected to the second gate electrode 2G.

The second gate electrode 2G is turned off before a turn-off operation; thus, the Cgc in the lower active part 51 of each of the two-part active trench A1/A1 and the two-part active trench A2/A2 and the lower electrode 7 of the two-part dummy active trench D/A can be reduced. The upper active part 50 and the lower active part 51 of the two-part active trench A2/A2 are connected to the second gate electrode 2G; thus, the lower active part 51 of the two-part active trench A1/A1, the upper active part 50 of the two-part active trench A2/A2, the lower active part 51 of the two-part active trench A2/A2, and the lower electrode 7 of the two-part dummy active trench D/A connected to the second gate electrode 2G can be closed before the channel of the upper active part 50 of the two-part active trench A1/A1 connected to the first gate electrode G is turned off. Accordingly, carriers in the drift layer 11 can be reduced, and turn-off loss can be reduced.

### Embodiment 5

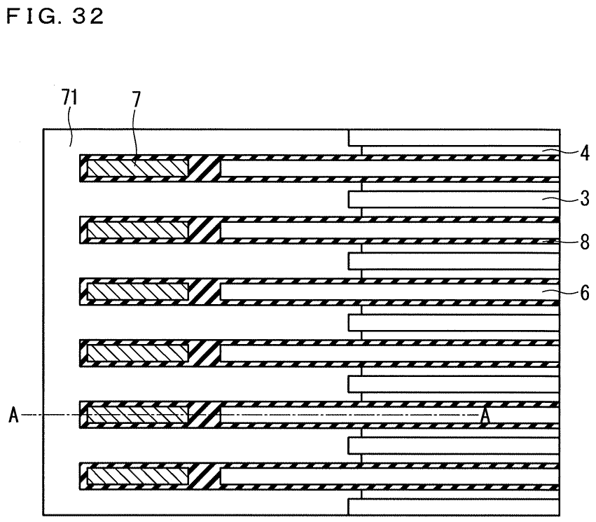

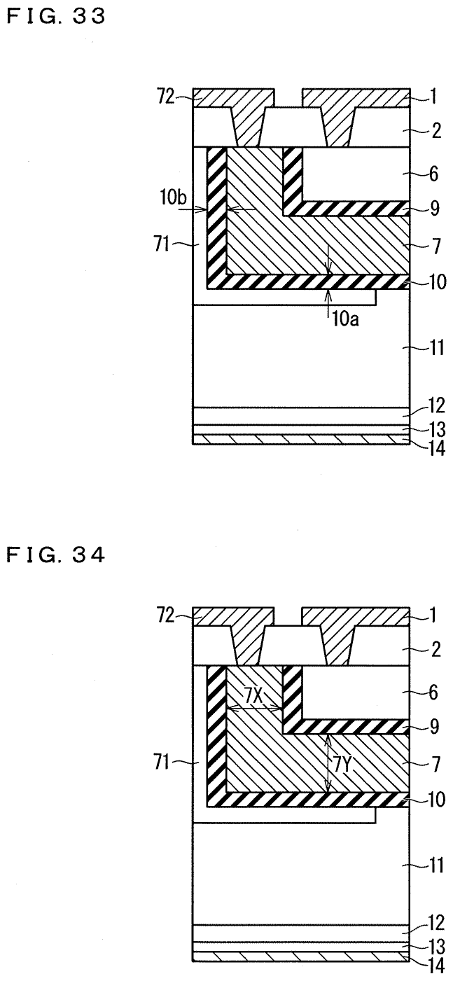

FIG. 32 is a plan view of a contact lifting part, and illustrates an end portion structure for connecting the lower electrode 7 of the two-part dummy active trench D/A to a gate liner 72 (refer to FIGS. 33 and 34) and connecting the upper dummy part 6 to the emitter electrode 1. A p-type well layer 71 is provided to cover an end portion of the trench in FIG. 32. Since the well layer 71 is provided, electrical field can be reduced, and deterioration of an oxide film can be further suppressed. The well layer 71 may not be provided.

FIG. 33 is an A-A cross sectional view of FIG. 32, and illustrates an end portion structure of the two-part dummy active trench D/A. In FIG. 33, as an example, a film thickness of the lower insulating film 10 covering the lower electrode 7 and separating the lower electrode 7 from the drift layer 11 and the well layer 71 may be larger than that of the boundary insulating film 9 separating the upper dummy part 6 from the lower electrode 7. According to such a configuration, insulation properties gets high between the lower electrode 7 and the drift layer 11 and between the lower electrode 7 and the well layer 71; thus, such a configuration contributes to improvement of reliability of the semiconductor device.

In FIG. 33, as another example, the film thickness of the boundary insulating film 9 separating the upper dummy part 6 from the lower electrode 7 may be larger than that of the lower insulating film 10 separating the lower electrode 7 from the drift layer 11 and the well layer 71. According to such a configuration, insulation properties gets high between the upper dummy part 6 and the lower electrode 7; thus, such a configuration contributes to improvement of reliability of the semiconductor device.

FIG. 34 is an A-A cross sectional view of FIG. 32, and illustrates an end portion structure of the two-part dummy active trench D/A. In FIG. 34, as an example, a width 7X in the horizontal direction of a position in which the lower electrode 7 and the upper dummy part 6 are arranged in the horizontal direction (the right-left direction) may be larger than a height 7Y in the up-down direction of the lower electrode 7 located below the upper dummy part 6. According to such a configuration, the contact connection part can be ensured; thus, a dimension tolerance of contact can be reduced.

In FIG. 34, as another example, the width 7X in the horizontal direction of the position in which the lower electrode 7 and the upper dummy part 6 are arranged in the horizontal direction (the right-left direction) may be smaller than the height 7Y in the up-down direction of the lower electrode 7 located below the upper dummy part 6. According to such a configuration, the contact connection part is shrunk and a proportion of the contact connection part in a surface area of a chip decreases; thus, an effective area of a cell can be increased.

### Modification Example 1

In FIG. 33, a film thickness 10b in the right-left direction is larger than a film thickness 10a in the up-down direction in the film thickness of the lower insulating film 10 separating the lower electrode 7 from the drift layer 11 and the well layer 71.

Electrical field is concentrated more easily in the end portion of the trench by an effect of the shape thereof, and the electrical field is increased more in a sidewall of the trench having contact with the semiconductor layer than in a bottom part of the trench particularly in the end portion of the trench. The reason is that since there is no adjacent trench in a region of the end portion of the trench, an electrical field shielding effect by the trench is not obtained. There arises a problem that avalanche occurs by the electrical field concentration, and a hole occurring by avalanche is implanted into an oxide film to lead to deterioration of the oxide film. As described in the present modification example 1, the film thickness 10b in the right-left direction is larger than the film thickness 10a in the up-down direction in the film thickness of the lower insulating film 10; thus, deterioration of the oxide film in a side part of the trench in which the electrical field is concentrated can be suppressed. It is sufficient that the film thickness 10b in the right-left direction is 1.1 times as large as the film thickness 10a in the up-down direction or more, and it is preferably 1.2 times as large as that or more, and is more preferably 1.5 times as large as that or more. According to such a configuration, deterioration of the oxide film can be further suppressed.

Each embodiment can be arbitrarily combined, or each embodiment can be appropriately varied or omitted within the scope of the present disclosure.

### APPENDIX

The aspects of the present disclosure are collectively described hereinafter as appendixes.

### Appendix 1

A semiconductor device, comprising:
a semiconductor substrate;
an emitter electrode formed on the semiconductor substrate;
a drift layer of a first conductivity type formed in the semiconductor substrate;
a base layer of a second conductivity type formed on a side of an upper surface of the semiconductor substrate;
a collector electrode formed below the semiconductor substrate; and
at least one two-part dummy active trench including an upper dummy part which is not connected to a gate electrode but is covered by an upper insulating film in an upper part and a lower electrode connected to the gate electrode and covered by a lower insulating film in a lower part inside a trench of the semiconductor substrate, wherein
a film thickness of the lower insulating film in a right-left direction is larger than a film thickness of the upper insulating film in a right-left direction, and
a ratio of an area of the lower insulating film to an area of the lower electrode is equal to or larger than 0.7 in a cross-sectional view.

### Appendix 2

The semiconductor device according to Appendix 1, wherein a film thickness of the lower insulating film in an up-down direction is larger than a film thickness of the upper insulating film in the right-left direction.

### Appendix 3

The semiconductor device according to Appendix 2, wherein
the film thickness of the lower insulating film in the up-down direction is larger than the film thickness of the lower insulating film in the right-left direction.

### Appendix 4

The semiconductor device according to Appendix 1, wherein
an area of the lower electrode is smaller than an area of the upper dummy part in a cross-sectional view.

### Appendix 5

The semiconductor device according to Appendix 1, wherein
the area of the lower electrode is larger than the area of the upper dummy part in a cross-sectional view.

### Appendix 6

The semiconductor device according to any one of Appendixes 1 to 5, wherein
a length of the lower electrode in an up-down direction is larger than a length of the upper dummy part in an up-down direction.

### Appendix 7

The semiconductor device according to any one of Appendixes 1 to 5, wherein
a length of the lower electrode in an up-down direction is smaller than a length of the upper dummy part in an up-down direction.

### Appendix 8

The semiconductor device according to any one of Appendixes 1 to 7, wherein
the two-part dummy active trench includes a boundary insulating film between the upper dummy part and the lower electrode, and
a film thickness of the boundary insulating film in an up-down direction is larger than the film thickness of the upper insulating film in the right-left direction.

### Appendix 9

The semiconductor device according to any one of Appendixes 1 to 8, wherein
the upper dummy part is metal.

### Appendix 10

The semiconductor device according to any one of Appendixes 1 to 9, wherein
the upper dummy part has higher specific resistance than the lower electrode.

### Appendix 11

The semiconductor device according to any one of Appendixes 1 to 9, wherein
the upper dummy part has lower specific resistance than the lower electrode.

### Appendix 12

The semiconductor device according to any one of Appendixes 1 to 8, wherein
the upper dummy part is floating potential.

### Appendix 13

The semiconductor device according to Appendix 9, wherein
the upper dummy part has contact with the base layer.

### Appendix 14

The semiconductor device according to Appendix 13, wherein
the upper insulating film has a concave shape in a cross-sectional view.

### Appendix 15

The semiconductor device according to any one of Appendixes 1 to 14, wherein
the lower electrode faces the base layer and the drift layer in a right-left direction via the lower insulating film.

### Appendix 16

The semiconductor device according to any one of Appendixes 1 to 14, wherein
the lower electrode faces only the drift layer in a right-left direction via the lower insulating film.

### Appendix 17

The semiconductor device according to any one of Appendixes 1 to 16, wherein
a length of the lower electrode in an up-down direction is smaller than a length of the lower electrode in a right-left direction.

### Appendix 18

The semiconductor device according to any one of Appendixes 1 to 17, further comprising
a carrier accumulation layer of a first conductivity type between the base layer and the drift layer.

### Appendix 19

The semiconductor device according to any one of Appendixes 1 to 18, further comprising
at least one active trench including a gate insulating film provided along a trench of the semiconductor substrate and an active part provided to have contact with the gate insulating film and connected to the gate electrode.

### Appendix 20

The semiconductor device according to any one of Appendixes 1 to 19, further comprising
a two-part active trench including a gate insulating film provided along a trench of the semiconductor substrate and an upper active part and a lower active part provided to have contact with the gate insulating film, connected to the gate electrode, and separated from each other via a boundary insulating film.

### Appendix 21

The semiconductor device according to Appendix 19, wherein
the two or more two-part dummy active trenches or the two or more active trenches are provided side by side or both the two or more two-part dummy active trenches and the two or more active trenches are provided side by side.

### Appendix 22

The semiconductor device according to Appendix 21, wherein
a total number of the two-part dummy active trenches is larger than a total number of the active trenches.

### Appendix 23

The semiconductor device according to Appendix 21, wherein
a total number of the two-part dummy active trenches is smaller than a total number of the active trenches.

### Appendix 24

The semiconductor device according to Appendix 19, further comprising
at least one dummy trench.

### Appendix 25

The semiconductor device according to Appendix 24, wherein
the two or more two-part dummy active trenches are provided side by side.

### Appendix 26

The semiconductor device according to Appendix 24, wherein
the two or more dummy trenches are provided side by side.

### Appendix 27

The semiconductor device according to any one of Appendixes 1 to 26, further comprising
a two-part floating active trench including an upper dummy part as floating potential covered by an upper insulating film in an upper part and a lower electrode connected to the gate electrode and covered by a lower insulating film in a lower part inside a trench of the semiconductor substrate.

### Appendix 28

The semiconductor device according to Appendix 21, wherein
an interval between the two-part dummy active trench and the active trench is larger than an interval between the two two-part dummy active trenches adjacent to each other and an interval between the two active trenches adjacent to each other.

### Appendix 29

The semiconductor device according to Appendix 20, wherein
the two or more two-part dummy active trenches or the two or more two-part active trenches are provided side by side or both the two or more two-part dummy active trenches and the two or more two-part active trenches are provided side by side.

### Appendix 30

The semiconductor device according to Appendix 29, wherein
a total number of the two-part dummy active trenches is larger than a total number of the two-part active trenches.

### Appendix 31

The semiconductor device according to Appendix 29, wherein
a total number of the two-part dummy active trenches is smaller than a total number of the two-part active trenches.

### Appendix 32

The semiconductor device according to Appendix 29, wherein an interval between the two-part dummy active trench and the two-part active trench is larger than an interval between the two two-part dummy active trenches adjacent to each other and an interval between the two two-part active trenches adjacent to each other.

### Appendix 33

The semiconductor device according to Appendix 19, wherein
the gate electrode includes a first gate electrode and a second gate electrode of a system different from the first gate electrode, and
the active part is connected to the first gate electrode, and the lower electrode is connected to the second gate electrode.

### Appendix 34

The semiconductor device according to Appendix 19, wherein
the gate electrode includes a first gate electrode and a second gate electrode of a system different from the first gate electrode,
the active trench includes a first active trench and a second active trench, and the active part of the first active trench is connected to the first gate electrode, and
the active part of the second active trench and the lower electrode are connected to the second gate electrode.

### Appendix 35

The semiconductor device according to Appendix 20, wherein
the gate electrode includes a first gate electrode and a second gate electrode of a system different from the first gate electrode, and
the upper active part is connected to the first gate electrode, and the lower active part and the lower electrode are connected to the second gate electrode.

### Appendix 36

The semiconductor device according to Appendix 1, wherein
in a contact lifting part of the two-part dummy active trench, a film thickness of the lower insulating film is larger than a film thickness of a boundary insulating film separating the upper dummy part and the lower electrode.

### Appendix 37

The semiconductor device according to Appendix 1, wherein
in a contact lifting part of the two-part dummy active trench, a film thickness of the lower insulating film is larger than a film thickness of a boundary insulating film separating the upper dummy part and the lower electrode.

### Appendix 38

The semiconductor device according to Appendix 1, wherein
in a contact lifting part of the two-part dummy active trench, a width of the lower electrode in a right-left direction in a position in which the lower electrode and the upper dummy part are arranged side by side in a right-left direction is larger than a length of the lower electrode in an up-down direction in a position in which the lower electrode and the upper dummy part are arranged side by side in an up-down direction.

### Appendix 39

The semiconductor device according to Appendix 1, wherein
in a contact lifting part of the two-part dummy active trench, a width of the lower electrode in a right-left direction in a position in which the lower electrode and the upper dummy part are arranged side by side in a right-left direction is smaller than a length of the lower electrode in an up-down direction in a position in which the lower electrode and the upper dummy part are arranged side by side in an up-down direction.

### Appendix 40

The semiconductor device according to Appendix 1, wherein
in a contact lifting part of the two-part dummy active trench, a film thickness of the lower insulating film in a right-left direction in a position in which the lower electrode and the upper dummy part are arranged side by side in a right-left direction is larger than a film thickness of the lower insulating film in an up-down direction in a position in which the lower electrode and the upper dummy part are arranged side by side in an up-down direction.

While the disclosure has been shown and described in detail, the foregoing description is in all aspects illustrative and not restrictive. It is therefore understood that numerous modifications and variations can be devised.

What is claimed is:

1. A semiconductor device, comprising:
a semiconductor substrate;
an emitter electrode formed on the semiconductor substrate;
a drift layer of a first conductivity type formed in the semiconductor substrate;
a base layer of a second conductivity type formed on a side of an upper surface of the semiconductor substrate;
a collector electrode formed below the semiconductor substrate; and
at least one two-part dummy active trench including an upper dummy part which is not connected to a gate electrode but is covered by an upper insulating film in an upper part and a lower electrode connected to the gate electrode and covered by a lower insulating film in a lower part inside a trench of the semiconductor substrate, wherein
a film thickness of the lower insulating film in a right-left direction is larger than a film thickness of the upper insulating film in a right-left direction, and
a ratio of an area of the lower insulating film to an area of the lower electrode is equal to or larger than 0.7 in a cross-sectional view.

2. The semiconductor device according to claim 1, wherein
a film thickness of the lower insulating film in an up-down direction is larger than a film thickness of the upper insulating film in the right-left direction.

3. The semiconductor device according to claim 2, wherein
the film thickness of the lower insulating film in the up-down direction is larger than the film thickness of the lower insulating film in the right-left direction.

4. The semiconductor device according to claim 1, wherein
an area of the lower electrode is smaller than an area of the upper dummy part in a cross-sectional view.

5. The semiconductor device according to claim 1, wherein
the area of the lower electrode is larger than the area of the upper dummy part in a cross-sectional view.

6. The semiconductor device according to claim 1, wherein
a length of the lower electrode in an up-down direction is larger than a length of the upper dummy part in an up-down direction.

7. The semiconductor device according to claim 1, wherein
a length of the lower electrode in an up-down direction is smaller than a length of the upper dummy part in an up-down direction.

8. The semiconductor device according to claim 1, wherein
the two-part dummy active trench includes a boundary insulating film between the upper dummy part and the lower electrode, and
a film thickness of the boundary insulating film in an up-down direction is larger than the film thickness of the upper insulating film in the right-left direction.

9. The semiconductor device according to claim 1, wherein
the upper dummy part is metal.

10. The semiconductor device according to claim 1, wherein
the upper dummy part has higher specific resistance than the lower electrode.

11. The semiconductor device according to claim 1, wherein
the upper dummy part has lower specific resistance than the lower electrode.

12. The semiconductor device according to claim 1, wherein
the upper dummy part is floating potential.

13. The semiconductor device according to claim 9, wherein
the upper dummy part has contact with the base layer.

14. The semiconductor device according to claim 13, wherein
the upper insulating film has a concave shape in a cross-sectional view.

15. The semiconductor device according to claim 1, wherein
the lower electrode faces the base layer and the drift layer in a right-left direction via the lower insulating film.

16. The semiconductor device according to claim 1, wherein
the lower electrode faces only the drift layer in a right-left direction via the lower insulating film.

17. The semiconductor device according to claim 1, wherein
a length of the lower electrode in an up-down direction is smaller than a length of the lower electrode in a right-left direction.

18. The semiconductor device according to claim 1, further comprising
a carrier accumulation layer of a first conductivity type between the base layer and the drift layer.

19. The semiconductor device according to claim 1, further comprising
at least one active trench including a gate insulating film provided along a trench of the semiconductor substrate and an active part provided to have contact with the gate insulating film and connected to the gate electrode.

20. The semiconductor device according to claim 1, further comprising
a two-part active trench including a gate insulating film provided along a trench of the semiconductor substrate and an upper active part and a lower active part provided to have contact with the gate insulating film, connected to the gate electrode, and separated from each other via a boundary insulating film.

21. The semiconductor device according to claim 19, wherein
the two or more two-part dummy active trenches or the two or more active trenches are provided side by side or both the two or more two-part dummy active trenches and the two or more active trenches are provided side by side.

22. The semiconductor device according to claim 21, wherein
a total number of the two-part dummy active trenches is larger than a total number of the active trenches.

23. The semiconductor device according to claim 21, wherein
a total number of the two-part dummy active trenches is smaller than a total number of the active trenches.

24. The semiconductor device according to claim 19, further comprising
at least one dummy trench.

25. The semiconductor device according to claim 24, wherein
the two or more two-part dummy active trenches are provided side by side.

26. The semiconductor device according to claim 24, wherein
the two or more dummy trenches are provided side by side.

27. The semiconductor device according to claim 1, further comprising
a two-part floating active trench including an upper dummy part as floating potential covered by an upper insulating film in an upper part and a lower electrode connected to the gate electrode and covered by a lower insulating film in a lower part inside a trench of the semiconductor substrate.

28. The semiconductor device according to claim 21, wherein
an interval between the two-part dummy active trench and the active trench is larger than an interval between the two two-part dummy active trenches adjacent to each other and an interval between the two active trenches adjacent to each other.

29. The semiconductor device according to claim 20, wherein
the two or more two-part dummy active trenches or the two or more two-part active trenches are provided side by side or both the two or more two-part dummy active trenches and the two or more two-part active trenches are provided side by side.

30. The semiconductor device according to claim 29, wherein
a total number of the two-part dummy active trenches is larger than a total number of the two-part active trenches.

31. The semiconductor device according to claim 29, wherein
a total number of the two-part dummy active trenches is smaller than a total number of the two-part active trenches.

32. The semiconductor device according to claim 29, wherein
an interval between the two-part dummy active trench and the two-part active trench is larger than an interval between the two two-part dummy active trenches adjacent to each other and an interval between the two two-part active trenches adjacent to each other.

33. The semiconductor device according to claim 19, wherein
the gate electrode includes a first gate electrode and a second gate electrode of a system different from the first gate electrode, and
the active part is connected to the first gate electrode, and the lower electrode is connected to the second gate electrode.

34. The semiconductor device according to claim 19, wherein
the gate electrode includes a first gate electrode and a second gate electrode of a system different from the first gate electrode,
the active trench includes a first active trench and a second active trench, and
the active part of the first active trench is connected to the first gate electrode, and the active part of the second active trench and the lower electrode are connected to the second gate electrode.

35. The semiconductor device according to claim 20, wherein
the gate electrode includes a first gate electrode and a second gate electrode of a system different from the first gate electrode, and
the upper active part is connected to the first gate electrode, and the lower active part and the lower electrode are connected to the second gate electrode.

36. The semiconductor device according to claim 1, wherein
in a contact lifting part of the two-part dummy active trench, a film thickness of the lower insulating film is larger than a film thickness of a boundary insulating film separating the upper dummy part and the lower electrode.

37. The semiconductor device according to claim 1, wherein
in a contact lifting part of the two-part dummy active trench, a film thickness of the lower insulating film is larger than a film thickness of a boundary insulating film separating the upper dummy part and the lower electrode.

38. The semiconductor device according to claim 1, wherein
in a contact lifting part of the two-part dummy active trench, a width of the lower electrode in a right-left direction in a position in which the lower electrode and the upper dummy part are arranged side by side in a right-left direction is larger than a length of the lower electrode in an up-down direction in a position in which the lower electrode and the upper dummy part are arranged side by side in an up-down direction.

39. The semiconductor device according to claim 1, wherein
in a contact lifting part of the two-part dummy active trench, a width of the lower electrode in a right-left direction in a position in which the lower electrode and the upper dummy part are arranged side by side in a right-left direction is smaller than a length of the lower electrode in an up-down direction in a position in which the lower electrode and the upper dummy part are arranged side by side in an up-down direction.

40. The semiconductor device according to claim 1, wherein
in a contact lifting part of the two-part dummy active trench, a film thickness of the lower insulating film in a right-left direction in a position in which the lower electrode and the upper dummy part are arranged side by side in a right-left direction is larger than a film thickness of the lower insulating film in an up-down direction in a position in which the lower electrode and the upper dummy part are arranged side by side in an up-down direction.
